(19) United States
(12) Patent Application Publication
(10) Pub. No.: US 2025/0262979 A1
(43) Pub. Date: Aug. 21, 2025

(54) STATE OF CHARGE ESTIMATION ACTIVATION WITH RESPECT TO SENSOR MEASUREMENT VALIDITY SIGNALS CONTROL

(71) Applicant: FCA US LLC, Auburn Hills, MI (US)

(72) Inventors: Heliasadat Jamaliskoei, Toronto (CA); Andrew White, Holly, MI (US); Mostafa Ahmed, Windsor (CA)

(21) Appl. No.: 18/581,977

(22) Filed: Feb. 20, 2024

(51) Int. Cl. B60L 58/12; G01R 31/367; G01R 31/388

(52) U.S. Cl. CPC B60L 58/12; G01R 31/367; G01R 31/388; B60L 2260/44; B60L 2260/52

(57) ABSTRACT

A state of charge (SOC) estimation method for a battery system of a vehicle includes obtaining a plurality of measurement signals indicative of measured parameters of the battery system, determining whether one or more of the plurality of measurement signals is corrupt or invalid, when one or more of the plurality of measurement signals is corrupt or invalid, (i) temporarily pausing a Kalman filter configured to estimate a SOC of the battery system and (ii) storing and utilizing a previously-estimated SOC of the battery system by the Kalman filter as the estimated SOC of the battery system, and when the plurality of measurement signals are valid or no longer corrupt, resuming operation of the Kalman filter to estimate the SOC of the battery system based on the plurality of measurement signals.

### FIELD

The present application generally relates to vehicle battery state of charge (SOC) estimation and, more particularly, to techniques for SOC estimation activation with respect to sensor measurement validity signals control.

### BACKGROUND

Today's vehicles often include one or more battery systems, such as low voltage (e.g., 12 volt, or V) batteries and, in hybrid/electrified vehicle applications, high voltage (48 V, 400 V, etc.) battery packs or systems. One of the primary functions of a battery pack control module (BPCM) in a vehicle is estimating the SOC of a particular battery system. One of the most accurate and robust battery system SOC estimation methods is utilizing a Kalman filter. This involves modeling the battery system (i.e., an equivalent circuit battery model) and recursively estimating the battery system states (including SOC) based on previously-estimated states and other measurement signals, such as voltage (V), current (I), and temperature (T). In some cases, these measurement signals temporarily become corrupt or invalid, which could result in the Kalman filter SOC estimation drifting away from the true value over time. Accordingly, while such conventional vehicle battery SOC estimation systems do work for their intended purpose, there exists an opportunity for improvement in the relevant art.

### SUMMARY

According to one example aspect of the invention, a state of charge (SOC) estimation system for a battery system of a vehicle is presented. In one exemplary implementation, the SOC estimation system comprises a set of sensors configured to generate a plurality of measurement signals indicative of measured parameters of the battery system and a control system configured to receive the plurality of measurement signals, determine whether one or more of the plurality of measurement signals is corrupt or invalid, when one or more of the plurality of measurement signals is corrupt or invalid, (i) temporarily pause a Kalman filter configured to estimate a SOC of the battery system and (ii) store and utilize a previously-estimated SOC of the battery system by the Kalman filter as the estimated SOC of the battery system, and when the plurality of measurement signals are valid or no longer corrupt, resume operation of the Kalman filter to estimate the SOC of the battery system based on the plurality of measurement signals.

In some implementations, the control system is configured to enable the Kalman filter for estimating the SOC of the battery system when all of the plurality of measurement signals are valid or not corrupt. In some implementations, the measured parameters of the battery system include a voltage, a current, and a temperature.

In some implementations, the one or more corrupt or invalid measurement signals of the plurality of measurement signals are not used by the Kalman filter to estimate the SOC of the battery system. In some implementations, one or more of the plurality of measurement signals becomes corrupt or invalid due to a malfunction of a respective sensor of the set of sensors. In some implementations, one or more of the plurality of measurement signals becomes corrupt or invalid due to a malfunction of a controller area network (CAN) configured for communication between the control system and the set of sensors.

In some implementations, the control system is configured to utilize the previously-estimated SOC of the battery system as the estimated SOC of the battery system to prevent overcharging of the battery system. In some implementations, the control system is configured to utilize the previously-estimated SOC of the battery system as the estimated SOC of the battery system for determining and conveying, to a driver of the vehicle, a current range of the vehicle.

According to another example aspect of the invention, an SOC estimation method for a battery system of a vehicle is presented. In one exemplary implementation, the SOC estimation method comprises generating, by a set of sensors of the vehicle, a plurality of measurement signals indicative of measured parameters of the battery system, receiving, by a control system of the vehicle and from the set of sensors, the plurality of measurement signals, determining, by the control system, whether one or more of the plurality of measurement signals is corrupt or invalid, when one or more of the plurality of measurement signals is corrupt or invalid, (i) temporarily pausing, by the control system, a Kalman filter configured to estimate a SOC of the battery system and (ii) storing and utilizing, by the control system, a previously-estimated SOC of the battery system by the Kalman filter as the estimated SOC of the battery system, and when the plurality of measurement signals are valid or no longer corrupt, resuming, by the control system, operation of the Kalman filter to estimate the SOC of the battery system based on the plurality of measurement signals.

In some implementations, the method further comprises enabling, by the control system, the Kalman filter for estimating the SOC of the battery system when all of the plurality of measurement signals are valid or not corrupt. In some implementations, the measured parameters of the battery system include a voltage, a current, and a temperature.

In some implementations, the one or more corrupt or invalid measurement signals of the plurality of measurement signals are not used by the Kalman filter to estimate the SOC of the battery system. In some implementations, one or more of the plurality of measurement signals becomes corrupt or invalid due to a malfunction of a respective sensor of the set of sensors. In some implementations, one or more of the plurality of measurement signals becomes corrupt or invalid due to a malfunction of a CAN configured for communication between the control system and the set of sensors.

In some implementations, utilizing the previously-estimated SOC of the battery system as the estimated SOC of the battery system prevents overcharging, by the control system, of the battery system. In some implementations, utilizing the previously-estimated SOC of the battery system as the estimated SOC of the battery system includes determining, by the control system, and conveying, by the control system and to a driver of the vehicle, a current range of the vehicle.

Further areas of applicability of the teachings of the present application will become apparent from the detailed description, claims and the drawings provided hereinafter, wherein like reference numerals refer to like features throughout the several views of the drawings. It should be understood that the detailed description, including disclosed embodiments and drawings referenced therein, are merely exemplary in nature intended for purposes of illustration only and are not intended to limit the scope of the present disclosure, its application or uses. Thus, variations that do not depart from the gist of the present application are intended to be within the scope of the present application.

### BRIEF DESCRIPTION OF THE DRAWINGS

FIG. 1 is a functional block diagram of a vehicle having a battery pack control module (BPCM) configured to perform a state of charge (SOC) estimation technique according to the principles of the present application; and

FIG. 2 is a flow diagram of an example SOC estimation method for a vehicle having a battery system and a set of battery parameter sensors according to the principles of the present application.

### DESCRIPTION

As previously discussed, one or more of the measurement signals for parameters such as voltage (V), current (I), and temperature (I) of a battery system of a vehicle could temporarily become corrupt or invalid. This could result in a Kalman filter state of charge (SOC) estimation drifting away from the true value over time. Once the measurement signals are valid or no longer corrupt, the Kalman filter SOC estimation will eventually correct itself (i.e., recover to the true value), but this recovery time could be long. Because the estimated SOC is a critical parameter that could be communicated to and utilized by a wide array of vehicle systems, ensuring SOC estimation accuracy is critical. An inaccurate estimated SOC could result in, for example only, a battery system being inadvertently overcharged (and potentially damaged as a result) and an inaccurate vehicle range being conveyed to a driver of the vehicle.

Accordingly, improved vehicle battery system SOC estimation techniques are presented herein. To briefly summarize, these improved vehicle battery SOC estimation techniques only enable the Kalman filter SOC estimation when all of the relevant measurement signals are valid (e.g., as indicated by respective validity flags). In other words, the Kalman filter could be temporarily paused when any of the measurement signals become corrupt or invalid, and the previously-estimated SOC could be latched/stored and temporarily utilized until the all of the measurement signals are again valid. Thereafter, the Kalman filter can resume battery system SOC estimation using the measurement signals as inputs. Potential benefits include improved vehicle system control and an improved driver experience ((e.g., by not utilizing/conveying an inaccurate SOC value).

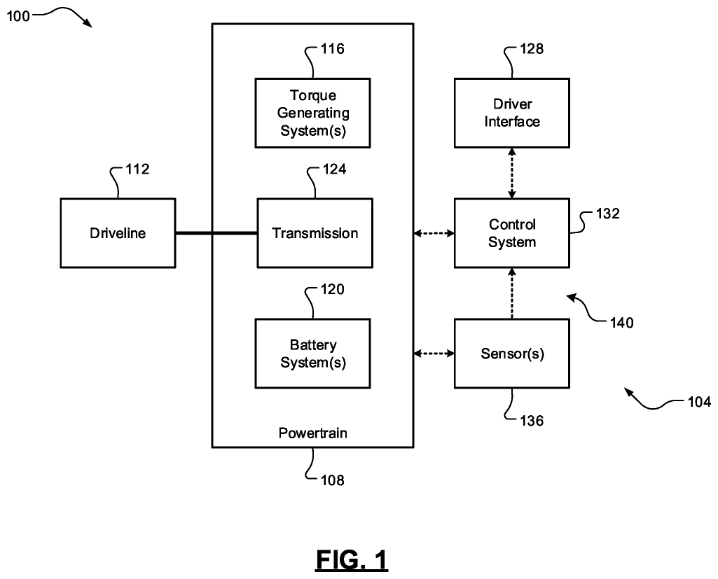

Referring now to FIG. 1, a functional block diagram of a vehicle 100 having an example SOC estimation system 104 according to the principles of the present application is illustrated. The vehicle 100 has any suitable configuration (conventional engine-only, hybrid, electric-only, etc.) and generally comprises a powertrain 108 that generates and transfers torque to a driveline 112 for propulsion. The powertrain 108 includes a set of torque generating systems 116 and a set of battery systems 120. The torque generating systems 116 include one or more electric motors (traction motor(s), starter-generator motor(s), etc.), an internal combustion engine, or some combination thereof. The battery system(s) 120 could include a low voltage (e.g., 12 volt, or V) battery and, in some implementations, one or more high voltage (48V, 400V, etc.) battery packs or systems. In some implementations, the powertrain 108 includes a transmission 124 (e.g., a multi-speed automatic transmission) configured to transfer the drive torque from the torque generating system(s) 116 to the driveline 112.

A controller or control system 132 is configured to control operation of the vehicle 100, including primarily controlling the powertrain 108 to generate and transfer a desired amount of drive torque to the driveline 112 to satisfy a torque request from a driver of the vehicle 100 provided by the driver via a driver interface 128 (e.g., an accelerator pedal). The driver interface 128 could also include other components to receive input from and/or output information to the driver, such as, but not limited to, an instrument panel cluster (IPC) or infotainment display. For example only, the driver interface 128 could be configured to display a current range of the vehicle 100 (e.g., miles remaining) based on an estimated SOC of a particular battery system 120 as discussed in greater detail herein.

The control system 132 is also configured to receive measurement signals from a set of sensors 136 (e.g., an intelligent battery sensor, or IBS), which could be configured to measure parameters of the battery system(s) 120 (voltage, current, temperature, etc.) and generate measurement signals indicative thereof. While the control system 132 is shown to be a general control system for the vehicle 100, it will be appreciated that the control system 132 could include a plurality of distributed electronic control units (ECUs) or modules, such as, but not limited to, an engine control module (ECM), a hybrid control processor (HCP), a transmission control module (TCM), and a battery pack control module (BPCM). The BPCM, for example, could be a sub-controller where the techniques of the present application are primarily implemented. The control system 132 (including any of its various sub-controllers, if applicable) and the set of sensors 136 are configured to communicate with one another via messages/signals transmitted and received on a controller area network (CAN) 140 or other suitable intra-vehicle communication network.

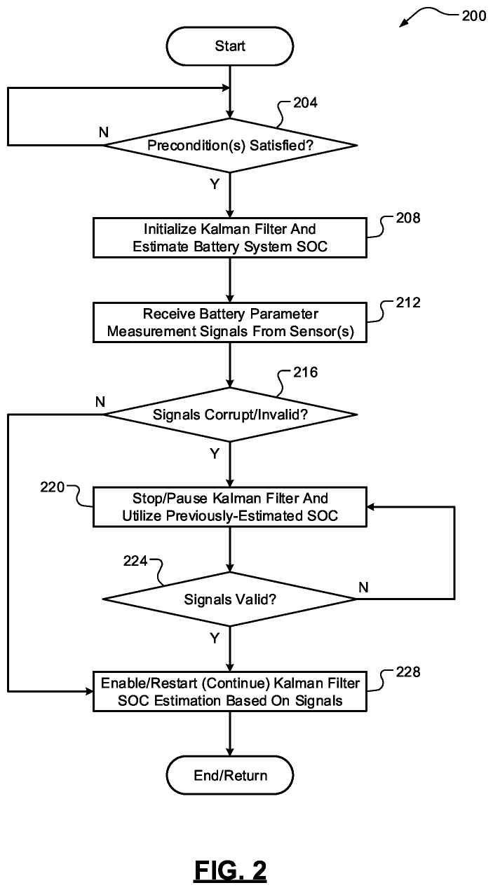

Referring now to FIG. 2, a flow diagram of an example SOC estimation method 200 for a vehicle according to the principles of the present application is illustrated. While the vehicle 100 and its components are specifically referenced for illustrative/descriptive purposes, it will be appreciated that the method 200 could be applicable to any suitably configured vehicle having a controller/sensors configured to estimate battery SOC using a Kalman filter. The method 200 begins at 204. At 204, the control system 132 determines whether a set of one or more optional preconditions are satisfied. This could include, for example only, the vehicle 100 being powered up and running and there being no malfunctions present that would negatively impact or otherwise inhibit the operation of the techniques of the present application. When false, the method 200 ends or returns to 204. When true, the method 200 proceeds to 208.

At 208, the control system 132 initializes a Kalman filter and begins estimating the SOC of a particular battery system 120 based on the measurement signals received from the set of sensors 136. These measurement signals could be indicative of, for example, voltage (V), current (I), and temperature (T) of the battery system 120. It will be appreciated that the measurement signals could include additional or alternative signals, such as a measured open circuit voltage (OCV) of the battery system 120. The initialization of the Kalman filter produces an initial estimation of various states of the battery system 120, including SOC, based on the plurality of measurement signals. At 212, the control system 132 receives the measurement signals from the sensor(s) 136. It will be appreciated that previous versions/samples of the measurement signals could have already been received by the control system 132 and utilized in initializing the Kalman filter to obtain an initial SOC estimation of the battery system 120.

At 216, the control system 132 determines whether any of the plurality of measurement signals have become corrupt or invalid. This could be indicated, for example, by a validity flag set by the sensor(s) 136 for or by another component on the CAN 140 for each of the plurality of measurement signals. This corruption or invalidity of the signal(s) could be caused by, for example only, a temporary malfunction of one of the sensor(s) 136, by a communication malfunction via the CAN 140, or some combination thereof. For example only, two measurement signals (V and T) could be valid but one measurement signal (I) could be corrupt or invalid. When false, the method 200 proceeds to 228. When true, the method 200 proceeds to 220. At 220, the control system 132 stops, pauses, or disables the Kalman filter. In other words, the control system 132 does not utilize the measurement signals (one or more of which is invalid or corrupt) for estimating the SOC of the battery system 120. The control system 132, for example, could latch or store the previously-estimated SOC of the battery system 120 for subsequent usage during this period of signal invalidity/corruption.

The use of the previously-estimated SOC as the estimated SOC of the battery system 120 could be for a variety of different purposes. One specific example is controlling recharging of the battery system 120. By utilizing the previously-estimated SOC that is known to be accurate/valid, inadvertent overcharging of the battery system 120 can be avoided, which could prevent potential damage thereto or general reduction in the life of the battery system 120.

Another specific example is displaying a vehicle range to the driver of the vehicle 100, such as via the driver interface 128. For example, in hybrid or electric-only configurations of the vehicle 100 that do not have an engine, the estimated SOC of a high voltage battery pack or system is a primary or sole component of the vehicle range (e.g., mileage until empty). The previously-estimated SOC could thus be utilized in determining the current vehicle range and conveying such information (e.g., via a display of the driver interface 128) to the driver.

At 224, the control system 132 determines whether the plurality of measurement signals (i.e., all of the measurement signals) are valid (i.e., no longer invalid or corrupt). When false, the method 200 returns to 220 where the previously-estimated SOC is continued to be utilized as the current estimated SOC of the battery system 120. In some implementations, after a certain period of measurement signal corruption/invalidity, there could be a timeout where a malfunction or fault could be detected and the vehicle 100 could be required to be serviced in order to fix another source of the corruption/invalidity of the measurement signals from the sensor(s) 136 (e.g., sensor replacement). When true (i.e., when all of the measurement signals are valid), the method 200 proceeds to 228. At 228, the control system 132 restarts, resumes, or enables (or continues estimating, from step 216) the Kalman filter SOC estimation based on the plurality of measurement signals (as well as the previous states, such as the previously-estimated SOC). The method 200 then ends or returns to 204 for one or more additional cycles.

It will be appreciated that the terms “controller” and “control system” as used herein refer to any suitable control device or set of multiple control devices that is/are configured to perform at least a portion of the techniques of the present application. Non-limiting examples include an application-specific integrated circuit (ASIC), one or more processors and a non-transitory memory having instructions stored thereon that, when executed by the one or more processors, cause the controller to perform a set of operations corresponding to at least a portion of the techniques of the present application. The one or more processors could be either a single processor or two or more processors operating in a parallel or distributed architecture.

It should also be understood that the mixing and matching of features, elements, methodologies and/or functions between various examples may be expressly contemplated herein so that one skilled in the art would appreciate from the present teachings that features, elements and/or functions of one example may be incorporated into another example as appropriate, unless described otherwise above.

What is claimed is:

1. A state of charge (SOC) estimation system for a battery system of a vehicle, the SOC estimation system comprising:
a set of sensors configured to generate a plurality of measurement signals indicative of measured parameters of the battery system; and
a control system configured to:
receive the plurality of measurement signals;
determine whether one or more of the plurality of measurement signals is corrupt or invalid;
when one or more of the plurality of measurement signals is corrupt or invalid:
(i) temporarily pause a Kalman filter configured to estimate a SOC of the battery system, and
(ii) store and utilize a previously-estimated SOC of the battery system by the Kalman filter as the estimated SOC of the battery system; and
when the plurality of measurement signals are valid or no longer corrupt, resume operation of the Kalman filter to estimate the SOC of the battery system based on the plurality of measurement signals.

2. The SOC estimation system of claim 1, wherein the control system is configured to enable the Kalman filter for estimating the SOC of the battery system when all of the plurality of measurement signals are valid or not corrupt.

3. The SOC estimation system of claim 1, wherein the measured parameters of the battery system include a voltage, a current, and a temperature.

4. The SOC estimation system of claim 1, wherein the one or more corrupt or invalid measurement signals of the plurality of measurement signals are not used by the Kalman filter to estimate the SOC of the battery system.

5. The SOC estimation system of claim 4, wherein one or more of the plurality of measurement signals becomes corrupt or invalid due to a malfunction of a respective sensor of the set of sensors.

6. The SOC estimation system of claim 4, wherein one or more of the plurality of measurement signals becomes corrupt or invalid due to a malfunction of a controller area network (CAN) configured for communication between the control system and the set of sensors.

7. The SOC estimation system of claim 1, wherein the control system is configured to utilize the previously-estimated SOC of the battery system as the estimated SOC of the battery system to prevent overcharging of the battery system.

8. The SOC estimation system of claim 1, wherein the control system is configured to utilize the previously-estimated SOC of the battery system as the estimated SOC of the battery system for determining and conveying, to a driver of the vehicle, a current range of the vehicle.

9. A state of charge (SOC) estimation method for a battery system of a vehicle, the SOC estimation method comprising:
generating, by a set of sensors of the vehicle, a plurality of measurement signals indicative of measured parameters of the battery system;
receiving, by a control system of the vehicle and from the set of sensors, the plurality of measurement signals;
determining, by the control system, whether one or more of the plurality of measurement signals is corrupt or invalid;
when one or more of the plurality of measurement signals is corrupt or invalid:
(i) temporarily pausing, by the control system, a Kalman filter configured to estimate a SOC of the battery system, and
(ii) storing and utilizing, by the control system, a previously-estimated SOC of the battery system by the Kalman filter as the estimated SOC of the battery system; and
when the plurality of measurement signals are valid or no longer corrupt, resuming, by the control system, operation of the Kalman filter to estimate the SOC of the battery system based on the plurality of measurement signals.

10. The SOC estimation method of claim 9, further comprising enabling, by the control system, the Kalman filter for estimating the SOC of the battery system when all of the plurality of measurement signals are valid or not corrupt.

11. The SOC estimation method of claim 9, wherein the measured parameters of the battery system include a voltage, a current, and a temperature.

12. The SOC estimation method of claim 9, wherein the one or more corrupt or invalid measurement signals of the plurality of measurement signals are not used by the Kalman filter to estimate the SOC of the battery system.

13. The SOC estimation method of claim 12, wherein one or more of the plurality of measurement signals becomes corrupt or invalid due to a malfunction of a respective sensor of the set of sensors.

14. The SOC estimation method of claim 12, wherein one or more of the plurality of measurement signals becomes corrupt or invalid due to a malfunction of a controller area network (CAN) configured for communication between the control system and the set of sensors.

15. The SOC estimation method of claim 9, wherein utilizing the previously-estimated SOC of the battery system as the estimated SOC of the battery system prevents overcharging, by the control system, of the battery system.

16. The SOC estimation method of claim 9, utilizing the previously-estimated SOC of the battery system as the estimated SOC of the battery system includes determining, by the control system, and conveying, by the control system and to a driver of the vehicle, a current range of the vehicle.
